(19) United States
(12) Patent Application Publication
(10) Pub. No.: US 2023/0305063 A1
(43) Pub. Date: Sep. 28, 2023

(54) INTELLIGENT POWER ALLOCATION FOR BATTERY PACK TESTING

(71) Applicant: Keysight Technologies, Inc., Santa Rosa, CA (US)

(72) Inventors: Andrey Popov, Bochum (DE); Eric Mares, Nordrhein Westfalen (DE); Roger Uhlenbrock, Bochum (DE)

(21) Appl. No.: 18/111,771

(22) Filed: Feb. 20, 2023

Related U.S. Application Data
(60) Provisional application No. 63/323,715, filed on Mar. 25, 2022.

(51) Int. Cl. G01R 31/36; G01R 31/367; H02J 7/00

(52) U.S. Cl. CPC G01R 31/3648; G01R 31/367; H02J 7/0013

(57) ABSTRACT

A battery pack test system includes a power cluster, a power router, a power allocation manager, and a plurality of test bench control units. The power cluster includes a plurality of power units. The power allocation manager is configured to dynamically switch allocations of power from individual power units of the plurality of power units to a plurality of test channels each connected to a different device under test. The plurality of test bench control units are each configured to interface with the power router and a different corresponding device under test. Each of the test bench control units includes a plurality of measurement sensors for measuring characteristics of the corresponding device under test.

### CROSS REFERENCE TO RELATED APPLICATIONS

This application claims priority under 35 U.S.C. § 119(e) from commonly owned U.S. Provisional Application No. 63/323,715 to Andrey Popov, et al. entitled “Intelligent Power Allocation For High-Power Battery Pack Test Laboratories” filed on Mar. 25, 2022. The entire disclosure of U.S. Provisional Application No. 63/323,715 is hereby incorporated by reference in its entirety.

### BACKGROUND

Recent developments in the automotive industry include electrification of vehicle powertrains. Batteries with high energy density and power output are needed to ensure electric vehicles (EVs) can achieve long range and high driving performance, and to ensure that the electric vehicles can be quickly charged. The development of such batteries is based on in-depth testing of individual battery cells, combined into modules and integrated battery packs, due to safety and performance requirements. To meet the demand for testing of different powertrain configurations, test laboratories use multiple test channels, which requires relatively large upfront investments in installed test equipment, grid-side power supply, and laboratory space. However, peak power levels are reached relatively rarely during endurance tests, such as during high acceleration of the electric vehicles, or during the first minutes of high-power charging, so the power equipment is not fully utilized. Operating costs for the many systems are high, whereas overall utilization is low.

In the endurance tests, individual battery packs may be subjected to load profiles for up to several weeks, and the load profiles represent typical loads on the battery packs over the lifetimes of the battery packs. Testing of battery packs for high-performance sports cars or trucks may require peak power levels of above 500 kilowatts (kW) and 1500 amperes (A) per axle. In a test lab where several battery packs are tested simultaneously, a total peak power of several megawatts may be expected.

A separate test bench system is typically dedicated to each device under test (DUT) due to complexity of the test bench system. As a result, each test bench system must also be designed for peak power, even if this only occurs occasionally. For lower powers and currents such as 270 kW and 900 A, a single test bench system may suffice. Current solutions suffer from drawbacks such as test systems being configurable only for a specific type of device under test, test systems lacking scalability, grouped test systems lacking galvanic isolation, and test systems lacking an ability to integrate with other test systems.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is an illustrative view of a system for intelligent power allocation for high-power test laboratories, in accordance with a representative embodiment.

FIG. 2A is another illustrative view of a system for intelligent power allocation for high-power test laboratories, in accordance with a representative embodiment.

FIG. 2B is another illustrative view of a system for intelligent power allocation for high-power test laboratories, in accordance with a representative embodiment.

FIG. 3 is an illustrative view of a switchbox of a power router for intelligent power allocation for high-power test laboratories, in accordance with a representative embodiment.

FIG. 4A is an illustrative view of a switch matrix for intelligent power allocation for high-power test laboratories, in accordance with a representative embodiment.

FIG. 4B is an illustrative view of a power allocation manager for intelligent power allocation for high-power test laboratories, in accordance with a representative embodiment.

FIG. 5A, FIG. 5B and FIG. 5C are an illustrative view of a method for intelligent power allocation for high-power test laboratories, in accordance with a representative embodiment.

FIG. 6A, FIG. 6B, FIG. 6C, FIG. 6D and FIG. 6E are an illustrative view of a method for intelligent power allocation for high-power test laboratories, in accordance with a representative embodiment.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only, and is not intended to be limiting. As used in the specification and appended claims, the singular forms of terms ‘a’, ‘an’ and ‘the’ are intended to include both singular and plural forms, unless the context clearly dictates otherwise. Additionally, the terms “comprises”, and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to”, “coupled to”, or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

As described herein, power units in a test facility may be clustered in a power cluster, and a power router may be configured to physically switch power outputs of the power units to where the power is needed. Power from power units may be intelligently and dynamically allocated to the test channels.

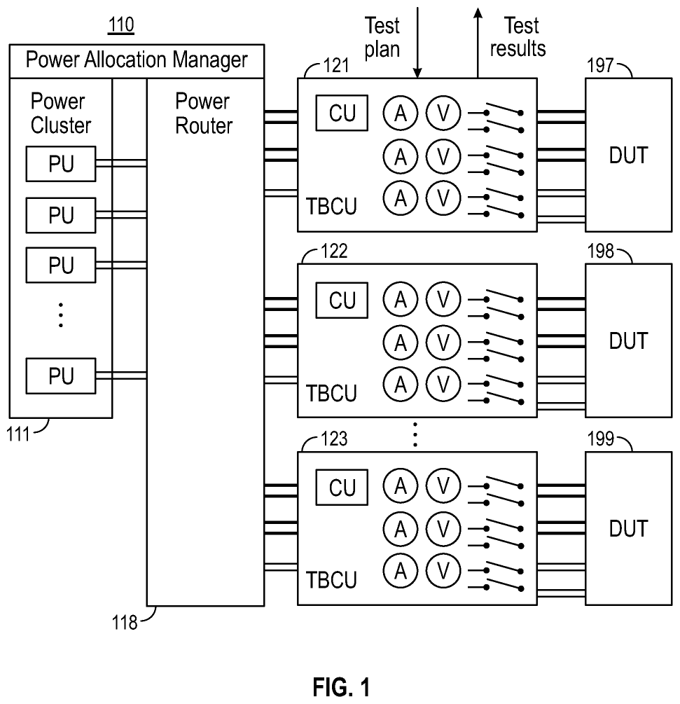

FIG. 1 is an illustrative view of a system for intelligent power allocation for high-power test laboratories, in accordance with a representative embodiment.

The system of FIG. 1 includes a power allocation manager 110 (which may be referred to as battery pack test system) and a plurality of test bench control units. For ease of illustration only three test bench units are shown. Specifically, a first test bench control unit 121, a second test bench control unit 122 and a third test bench control unit 123 are shown. The first test bench control unit 121 is interfaced with a first device under test (DUT) 197. The second test bench control unit 122 is interfaced with a second device under test (DUT) 198. The third test bench control unit 123 is interfaced with a third device under test (DUT) 199.

The power allocation manager 110 includes a power cluster 111 and a power router 118. The power cluster 111 includes a plurality of power units (PUs). Each power unit may individually provide power to some of the devices under test in FIG. 1. As an example, each individual power unit may provide 90 kilowatts (kW), 1500 volts (V), and 300 amperes (A). In other examples, a power unit may provide 20 kilowatts or 30 kilowatts. The power router 118 may include a programmable logic controller and a plurality of physical switches that are controlled by the programmable logic controller. The plurality of physical switches in the power router 118 is controlled by the programmable logic controller to switch power from the power units of the power cluster 111 to the devices under test.

As described more fully below, the power allocation manager 110 may include a programmable controller. The intelligence of the routing is in the power allocation manager. The power allocation manager (PAM) may include a programmable controller. The programmable controller may include a memory that stores instructions and a processor that executes the instructions. A routing algorithm executed by the programmable controller may provide for planning and executing optimal routing of the power provided by the power units in the power cluster 111 to the devices under test, in terms of minimal re-routing needed and satisfied power demands. The programmable controller may be configured to receive power requests from each of the test bench control units, generate an optimal routing plan for allocating power from the individual power units of the plurality of power units in the power cluster 111 to plurality of test channels to the devices under test. The programmable logic controller in the power router 118 may be configured to dynamically control the plurality of switches based on the optimal routing plan. Notably, the controller in the PAM commands the programmable logic controller (PLC) in the power router, which in turn commands the switches. The reason that PAM does not control these switches directly, but over the PLC in the power router, is because the PLC brings robustness and safety (due to implementation of the PLC), which allows monitoring switches and avoiding accidental opening/closing of switches.

A test plan may serve as the basis for the routing of power to any device under test from the power units of the power cluster 111. The devices under test may be provided power simultaneously from the power units of the power cluster 111 based on dynamic configurations and reconfigurations of the switches in the power router 118 based on the test plans for the devices under test. As described more fully below, the test plan may be a server-based test plan that is uploaded to the individual test bench control units (TBCUs) based on the types of devices under test to be tested. Accordingly, a TCBU 121 may implement different test plans at different times for different devices under test, A server (not shown) may store a set of test plans for the laboratory that includes the system of FIG. 1. A test plan may specify how much power is to be provided to a device under test, which channel is to be used to provide the power to the device under test at any one time, and how long the power is to be provided to a channel. The amount of power to be provided to any channel to a device under test may correspond to the number of power units to be used. In some embodiments, some power units may provide a first level of power, and other power units may provide a second level of power, different from the first, so that the amount of power to be provided is not strictly a linear function of the number of power units providing power. The test plan may specify amounts of power and lengths of time to provide the power by output locations corresponding to channels.

Each of the plurality of test bench control units includes a control unit (CU). Each TBCU 121 allows grouping and placement of relevant measurements and communication modules required for testing a corresponding device under test close to the corresponding device under test, such as on the side of the climate chamber closest to the device under test in the climate chamber. That is, required measurements and control for a device under test may be provided inside the corresponding test bench control unit rather than from any particular power unit, and power units may be dynamically allocated and re-allocated to different test bench control units and corresponding devices under test. A single test bench control unit may control several channels, such as several channels of a device under test. Each device under test may be provided with its own test bench control unit. Each of the plurality of test bench control units may be reconfigurable to adapt to multiple different devices under test. For example, different devices under test may have different power requirements and different numbers of channels, so each test bench control unit may be configured differently for each of multiple different devices under test at different times.

Modern battery packs typically have 2 to 5 output channels. The 2 to 5 outputs may include 2 outputs for the drive axles including one output for the front wheels one output for the rear wheels, as well as a high-power DC-charging channel, an output to onboard power consumers such as compressors, seat heating, etc., and one output to the onboard charger. The plurality of devices (DUTs) under test (e.g., first DUT 197, second DUT 198 and third DUT 199) may each comprise a battery pack with a plurality of individual battery cells. Each of the plurality of DUTs may have several high-power channels for the front and rear axle and for high-power charging, and one or more low power channels for onboard consumer electronics and chargers.

Using the configuration in FIG. 1, most or all power units of the power cluster 111 do not have to be dedicated to a specific channel on a permanent or semi-permanent basis. Additionally, the maximum power and current of each power unit may be selected such as to allow optimal quantization of step sizes and minimized hardware costs, in order to implement test plans for the devices under test. The number of power units may be variable, such as based on the requirements of the devices under test, and may be scalable. Additionally, power units may be deactivated when appropriate, such as if a power unit becomes defective, and power may be provided from another of the power units.

When devices under test vary at different times, such as with a different number of channels, current or power ratings, or specific requirements is present, only the test bench control units may require adaption for each device under test. That is, the test bench control units may be configurable and reconfigurable for different types of devices under test at different times.

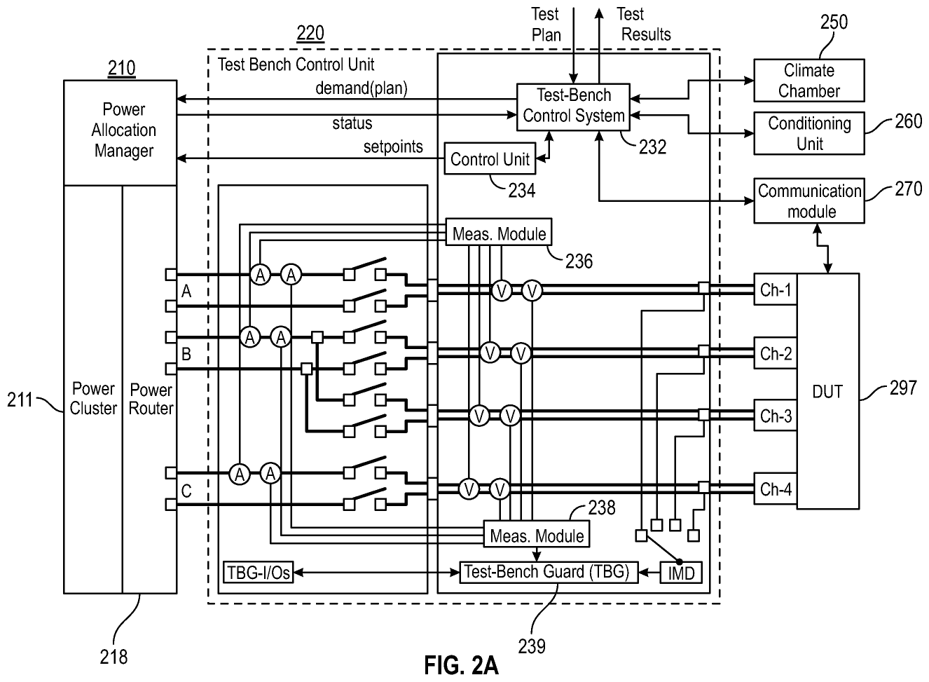

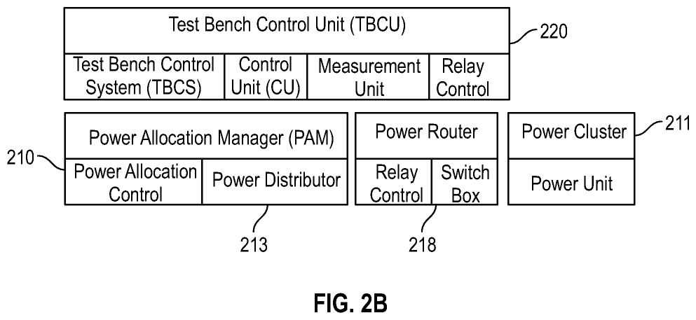

FIG. 2A is another illustrative view of a system for intelligent power allocation for high-power test laboratories, in accordance with a representative embodiment.

The system of FIG. 2A includes a power allocation manager 210, a test bench control unit 220, a climate chamber 250, a conditioning unit 260, and a communication module 270 (providing controller area network module or automotive Ethernet module). The test bench control unit 220 and the communication module 270 are interfaced with a device under test 297.

The power allocation manager 210 includes a power cluster 211 and a power router 218. The power cluster 211 includes a plurality of power units. The power router 218 includes a plurality of switches and routes power from each of the plurality of power units in the power cluster 211. The power allocation manager 210 may include some or all features and characteristics of the power allocation manager 110 in FIG. 1.

The test bench control unit 220 includes a test-bench control system 232, a control unit 234, a measurement module 238 and a test-bench guard 239 (TBG). The test bench control unit 220 may include sets of current sensors, voltage sensors and measurement modules. One set of such sensors may provide measurements for the current and voltage measurement and control. Another set of such sensors may possess relatively-lower accuracy and be used for redundant measurements for safety monitoring, and may be connected to a programmable logic controller that takes the role of a test-bench guard (TBG). The test-bench guard in the test bench control unit 220 may be implemented as safety logic executed by a processor. The test-bench guard monitors critical parameters of the battery pack, including voltage, temperature, and current, independently of the test plan. In a critical situation, the test-bench guard may be responsible for disconnecting all power contactors and bringing the system of FIG. 2A to a safe state both for the device under test and for the operating personal. An insulation monitoring device (IMD) may also be connected to the test-bench guard. Since all channels of the device under test are connected to the same battery pack inside the device under test, the insulation monitoring device may only need to monitor one of the channels.

The climate chamber 250 is a chamber in which the device under test is placed. The climate chamber 250 and any other climate chamber described herein may emulate environmental conditions, such as temperature and humidity.

The conditioning unit 260 serves as the cooling medium for the corresponding device under test.

The communication module 270 provides a combined hardware and software communication hub as a communication interface between the test bench control unit 220 and the device under test 297. As an example, to the communication module 270, the communication module 270 may provide controller area network (CAN) interface to the device under test.

FIG. 2B is another illustrative view of a system for intelligent power allocation for high-power test laboratories, in accordance with a representative embodiment.

The system in FIG. 2B includes a power allocation manager 210 (PAM), a test bench control unit 220, a power cluster 211 and a power router 218. The power cluster 211 and the power router 218 are shown separate from the power allocation manager 210, but may be components of the power allocation manager 210.

The power allocation manager 210 includes a power allocation controller (power allocation control module) and a power distributor 213 (power distribution module). The power allocation control module may include a software program with one or more algorithms provided as logical instructions for each step of a test plan, including how much power to provide in total, how many and which power units to use to provide the power, and how long the power is to be provided. The power distributor 213 may include a software program with one or more algorithms provided as logical instructions for controlling the communication of real-time measurements and control signals between the control units in the TBCUs 220 and the power units in the power cluster 211. When executed by a processor in the power allocation manager 210, the power allocation manager 210 illustratively may generate a test plan for controlling power allocation, and then implement the test plan by controlling power distribution by controlling switched in the power router 218.

The power router 218 includes a relay control module and a switch box. The switch box includes the switches of the power router 218. The switch box may include a matrix of switches that can be used to connect some or all of the power units to some or all of the devices under test. The relay control module (the programmable logic controller described above) may control connection and disconnection of power to the power router 218 from the power units.

A capability to connect a power unit (PU) of the power cluster 211 to a particular input of a specific test bench control unit is provided for the power router 218. That is, the power router 218 may have a structure similar to a traditional signal multiplexer, but for much higher currents, with two-pole switching, having requirements to perform switching and avoid shorting two devices under test, and requiring a minimized number of switches (power contactors).

The test bench control unit 220 includes a test bench control system (TBCS), a control unit (CU), a measurement unit and a relay control. The test bench control system may be implemented on an industrial personal computer (IPC) with a Linux operating system. The test bench control system may include test bench control software that is executed to control tests for a corresponding device under test in accordance with a test plan. The control unit may include a microcontroller, such as with an real-time operating system (RTOS), and a field-programmable gate array which implement control loops of voltage and current in real time. The test bench control software may be executed to interpret the test plan and send required source-operation commands to the control unit, and may also control other systems such as the climate chamber where the device under test is placed, a conditioning unit for a cooling medium, and the communication module that provides a communication interface to the device under test. The measurement unit may include instruments used to measure characteristics of the corresponding device under test as the test plan is implemented. The relay control may control connection and disconnection of power from the power router 218 to the corresponding device under test.

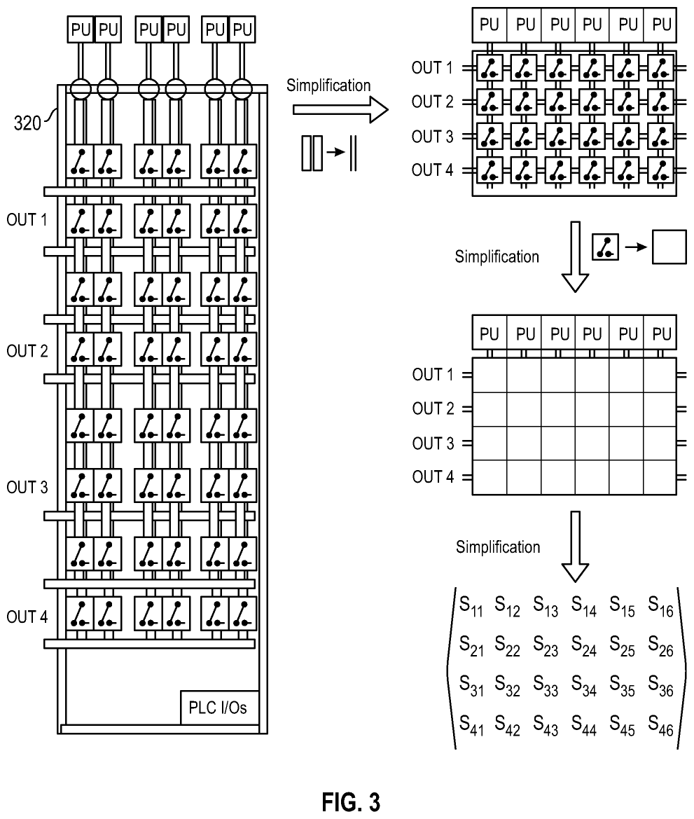

FIG. 3 is an illustrative view of a switch box of a power router for intelligent power allocation for high-power test laboratories, in accordance with a representative embodiment.

The switch box in FIG. 3 is a power switch box, and is shown in a progression of simplifications so that connection of the power units as inputs to the outputs to the test bench control units can be represented as a matrix. Each element of the matrix represents the state sᵢⱼ∈0, 1 of the corresponding switch in the switch box.

The simplifications of the power switchbox in FIG. 3 provide for a representation of connections between the power units and the test bench control units as a single switch matrix. This, in turn, provides for a representation of the connections between the power units and the device(s) under test. The overall switch matrix may be filled relatively sparsely, so that no connection from any power unit to any channel of a test bench control unit is shown, and this may reduce the hardware required inside a power router such as the power router 218. The switch matrix may be filled relatively sparsely, but as a consideration of a lower bound, a certain number of connections may be required to meet a peak power demand, and a redundancy to compensate for failures in power units may also be built into the switch matrix. The switch matrix representation may be used to identify optimal routing from the power units to the device(s) under test.

In the example of FIG. 3, the representation of the power switch box (PSB) has 6 two pole inputs connected to 6 power units, and any of the two pole inputs may be connected to any of 4 outputs. The power switch box comprises a cabinet for the power units. Two or more power switch boxes may be stacked together to scale to higher currents and power. Output busbars of two or more stacked power switch boxes may be connected. Power contactors may be used as the switching elements, and may include signal contactors that are forcibly driven and that can be monitored by the programmable logic controller (PLC) of the relay control of the power router 218. The power switch box may be a component of a power router, such as the power router 218 in FIG. 2A

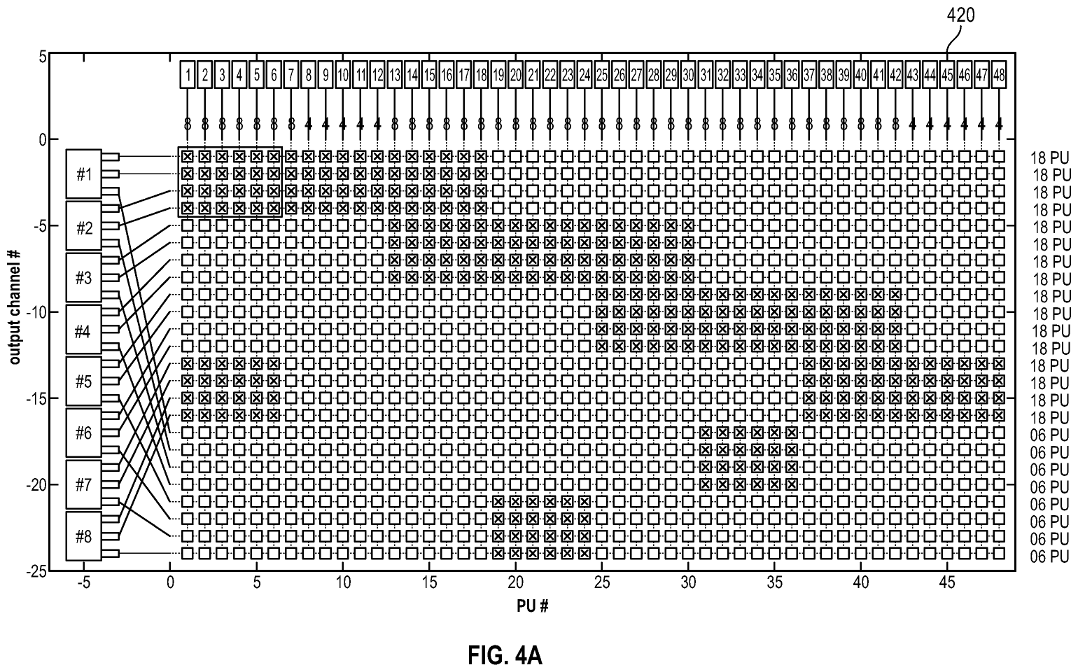

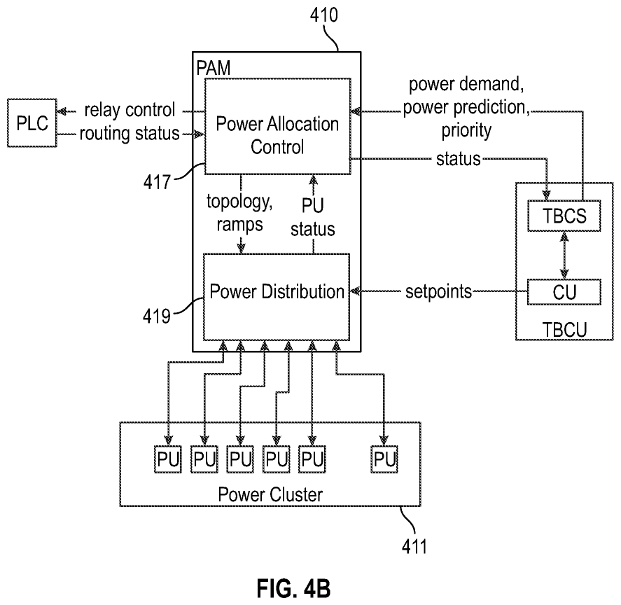

FIG. 4A is an illustrative view of a switch matrix for intelligent power allocation for high-power test laboratories, in accordance with a representative embodiment.

The switch matrix in FIG. 4A may be provided inside a power router, such as the power router 218 in FIG. 2A The switch matrix may represent interconnections between power units of the power cluster such as the power cluster 211 and channels of the device(s) under test.

As an example, a laboratory may have 8 devices under test, each with 3 channels. The 3 channels may include 2 high power channels and 1 low power for each device under test. Altogether 48 power units are provided as shown in FIG. 4A. The devices under test are shown on the left side of FIG. 4A and the power units on the top. The blocks with an “x” show the locations where a (two pole) switch is present. A power switch box with 4 outputs and 6 inputs, as the one in FIG. 3, is shown in the upper left corner. The numbers on the lines to the power unit and the right end of the diagram show the number of connections in the line. Note that channel number 3 of each device under test is the low power channels and thus connected to fewer power units, as shown in the bottom 8 rows. This representation of the power router 218 serves as an intuitive representation of an overall switch matrix.

FIG. 4B is an illustrative view of a power allocation manager for intelligent power allocation for high-power test laboratories, in accordance with a representative embodiment.

As shown in FIG. 4B, the power allocation manager 410 includes a power allocation control module 417 and a power distribution module 419. Power units are provided in a power cluster 411. The structure of the power allocation manager (PAM) and the interface to the power units in the power cluster 411 and a test bench control unit with a best bench control system and a control unit (CU) are shown. The power allocation manager in FIG. 4B is logically divided between the power allocation control module and the power distribution module.

The power allocation control module 417 receives power demands from the software of the test bench control systems, inside the test bench control units 220 in FIG. 2B, plans the optimal routing strategy, and commands the optimal routing strategy to a programmable logic controller (PLC) controlling the switches inside a power router such as the power router 218 in FIG. 2A, as well as to the power distribution module 419. The power allocation manager 410 is configured to dynamically re-route power, within the constraints of the power units, and the number of switching cycles the contactors inside the power router can withstand. Power allocation for a test plan may be calculated and recalculated with a sample time between 10 seconds and 5 minutes, for example.

The power demand may be determined based on the test plan. The test bench control systems may check the test step(s) before implementation. Relevant test steps are the ones that require a source to be active. Examples of these are current, voltage or power source, AC-signal measurements and constant current, and constant voltage (CCCV) charging. For the first three types of test step, the current and power demand may be readily computed by the test step parameters and the current state of the device under test.

For example, before activation of a channel in current source mode the parametrized current setpoint may be extracted from the test step. Multiplying this by the voltage of the device under test provides the power. Additionally, variation in the voltage of the device under test during the test step may be accounted for either by exploiting the maximal voltage of the device under test provided by the user, or by accounting that for modern Li-Ion cells the voltage of a fully charged battery pack is approximately 25% higher than the voltage of a discharged battery pack. This allows computation of the required maximal current and maximal power for the next few minutes, and the prediction can then also be adapted during operation to provide better estimates and finer granularity.

Similarly, for a constant current—constant voltage (CCCV) charging step, the maximal current may be specified by the test plan and the maximal power may be computed by multiplying this by the specified final voltage to hold. Additionally, the current and required power both rapidly decrease after reaching the target voltage. The battery management system (BMS) of a battery pack may communicate with the test bench control system and change one or more test limits. However, the battery management system may only be allowed to reduce the maximum current or/and power insofar as the primary task of the battery management system is to protect the battery pack, and protection may be limited to derating (reducing) the maximal power (or current) that the battery pack can provide.

The priorities of the individual test benches and devices under test may be specified on a laboratory level by management software which communicates directly with the test bench control system. Alternatively, the priorities of the individual test bench control units may be specified by the operator of the individual test bench control unit. These priorities are then used in case that the maximum power of the power cluster is reached, to decide which test bench should be halted or paused first.

The power distributor (PD) may be responsible for splitting the instantaneous current setpoints from the individual control units (CU) among the allocated power units. The number of parts in which current is to be split may depend on the routing inside the power router at any one time. As such the power distributor operates under hard real-time requirements and may be required to meet a low latency threshold. The high-speed serial interface for communication is only an example of the communication topology. Alternatively, since the selected power units have a high internal impedance (current sources) and can balance the currents between several units, interfaces slower than a high-speed serial interface may be provided, such as interfaces based on Ethernet with sampling rates of up to 5 k/s.

The power distributor is responsible for activating a new unit, synchronizing the new unit to the voltage of the device under test with a command setpoint of 0 current, and then appropriately ramping up the current once there is a change in the routing topology and power units need to be added or removed to a channel.

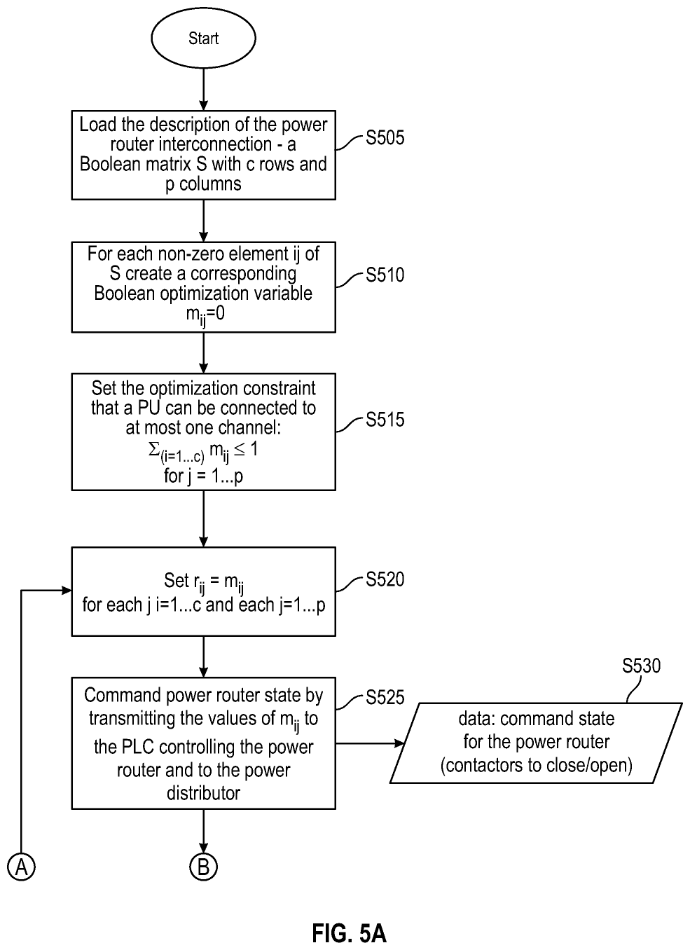

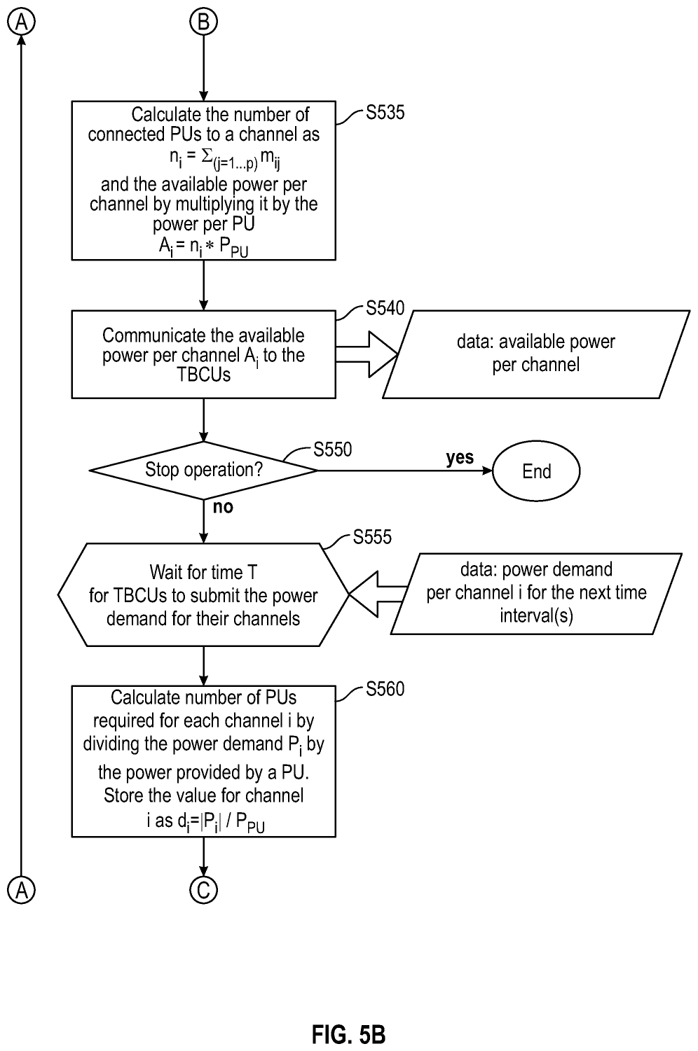

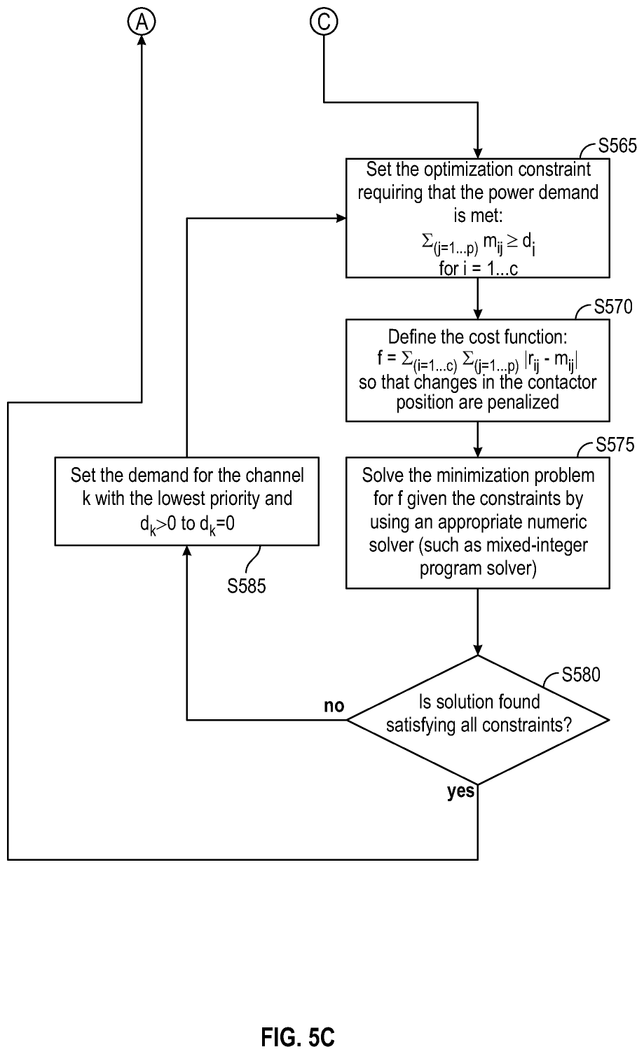

FIG. 5A, FIG. 5B and FIG. 5C are an illustrative view of a method for intelligent power allocation for high-power test laboratories, in accordance with a representative embodiment.

The method of FIG. 5A, FIG. 5B and FIG. 5C starts at S505 by loading a description of a power router interconnection as a Boolean matrix S with c rows and p columns.

At S510, for each non-zero element ij of the Boolean matrix S, a corresponding Boolean optimization variable mᵢⱼ is created.

At S515, an optimization constraint is set. The optimization constraint may specify that a power unit is to be connected to at most one channel as Σₘ₌₁^{c} mᵢⱼ≤1, for each j=1 . . . p.

At S520, the reference value rᵢⱼ of each Boolean optimization variable is set to be equal to mᵢⱼ.

At S525, a power router state is commanded. The power router state may be commanded by transmitting the values of mᵢⱼ to the programmable logic controller controlling the power router and to the power distributor.

At S530, data is sent to the power router as data for a command state to indicate whether contactors should be closed or open.

At S535, a number of power units connected to a channel is calculated as nᵢ=Σⱼ₌₁^{p} mᵢⱼ, and the available power per channel is calculated as Aᵢ=nᵢP_{PU}. The number of power units n is calculated for each channel i as a function of the optimization variables for the channel. The power per channel Aᵢ is calculated by multiplying the number of power units n by the power per power unit P_{PU}.

Given a switch matrix topology (as described above in connection with FIG. 4A) and power demand for each channel calculated in S535, the task of the power allocation control is to identify the optimal configuration of switches in the power router, such that the power demand at the output is satisfied. The problem may be represented mathematically and solved as an integer programming optimization problem. To describe this problem mathematically, for each output channel, the number of power units that are needed may be determined based on the power demand in the channel and the power capabilities of a single power unit. The power demand per channel and the power capabilities of each individual power unit may be determined to achieve the desired power or to achieve the desired current, and in both cases the number of power units may be determined as a whole number (non-negative integer). For each power unit, only one contactor may be closed, as otherwise two channels may be shorted. The switch matrix topology may be represented as a c×p Boolean matrix S, where 0 means no connection, and 1 means contactor present. Each of the c rows represents one of the output channels, and each p column represents one of the power units. Notably, the positions of the rows and the columns may be permutated without changing the result, as this is equivalent to renaming the power units or the channels. Each column of the Boolean matrix S may have at least one “1”—as otherwise an input is not connected. Each row of the Boolean matrix S may have at most one “1”—as otherwise and two DUTs will be shorted together. The representation of a switch matrix provided by a Boolean matrix S may also be used in the event that a power unit is integrated into or dedicated to a test bench control unit, as the corresponding row may have only one “1”, as the safety contactor in the test bench control unit may be what is represented in the switch matrix.

At time k, the state of the switch matrix may be represented with a second c×p Boolean matrix M(k), with 0 meaning that a contactor is open, and 1 meaning that the contactor closed. The representation of the switch matrix provided by the Boolean matrix M(k) allows representing arbitrary connections.

The search for M(k) may be posed as an integer optimization program. If mᵢⱼ∈0,1 are the coefficients of M that need to be determined, the pairs (i j) correspond to the non-zero positions of the Boolean matrix S (that is sᵢⱼ=1, and all other positions mᵢⱼ=0). If dᵢ∈W are the elements of the power demand vector D(k)∈W^{c}, and W is the set of whole numbers (non-negative integers), the following constraints may be imposed:
(i)—0≤mᵢⱼ≤1, for all m variables (that is, the i-j pairs, where sᵢⱼ=1)—the contactors are either closed or open→Boolean variables.
(ii)—∈ᵢ₌₁^{c} mᵢⱼ≤1, for each column j=1 . . . p—that is, a power unit may be connected to at most one row, that is to at most one DUT channel.
(iii)—Σⱼ₌₁^{p} mᵢⱼ≥dᵢ, for each row i=1 . . . c—that is each channel should have at least as many connections, as needed to meet the power demand.

Solving for the two inequalities (ii) and (iii), multiple solutions may exist. To reduce the size of possible solutions, the following objective function may be added: minimize the number of changed switch positions, compared to the previous state of M(k−1). Let rᵢⱼ be the states of the variables at k−1. Then the cost function in S570 is

$$f = {\sum }_{i = 1}^{c} {\sum }_{j = 1}^{p} \vert {r}_{ij} - {m}_{ij} \vert$$

As an example, the optimization approach for the switch matrix may be implemented in Matlab using the intlinprog solver of Matlab. A solution for the Boolean matrix S with c=16, p=72 may be reliably found in approximately 0.3 seconds of computation time. As a result, power allocation control may be executed in a range, for example, of 10 to 300 seconds.

The description of the routing problem as integer programming problem may allow for adding priorities for the channels. Priorities for channels may be used in the event the power of the power cluster is not sufficient for all channels at the same time. Additional constraints may be added to account for prediction of the power demand for each test bench control unit.

At S540, the available power per channel Aᵢ is communicated to the test bench control units.

At S550, a determination is made whether to stop the operation. If the operation is to be stopped (S550=Yes), the operation is ended.

If the operation is not to be stopped (S550=No), the method of FIG. 5A, FIG. 5B and FIG. 5C waits for time T for the test bench control units to submit the power demand for their channels for the next time interval(s).

At S560, the number of power units required for each channel i is calculated by dividing the power demand Pᵢ by the power provided by a power unit. The value for the number of power units required for each channel is stored for each channel i as dᵢ=|Pᵢ|/P_{PU}.

At S565, an optimization constraint is set. The optimization constraint requires that the power demand is met by Σⱼ₌₁^{p} mᵢⱼ≥dᵢ.

At S570, the cost function is defined as f=Σᵢ₌₁^{c}Σⱼ₌₁^{p}|rᵢⱼ−mᵢⱼ|.

At S575, a minimization problem is solved for f given the constraints. An appropriate numeric solver is used to solve the minimization problem, such as an integer program solver.

At S580, a determination is made whether a solution has been found satisfying all constraints.

If a solution is not found at S580 (S580=No), the method of FIG. 5A, FIG. 5B and FIG. 5C sets the demand for a channel to 0 at S585 and then returns to S565.

If a solution is found at S580 (S580=Yes), the method of FIG. 5A, FIG. 5B and FIG. 5C returns to S520 and the new state of the switching matrix is recorded by setting rᵢⱼ to be equal to mᵢⱼ and the method from S520 to S585 is repeated.

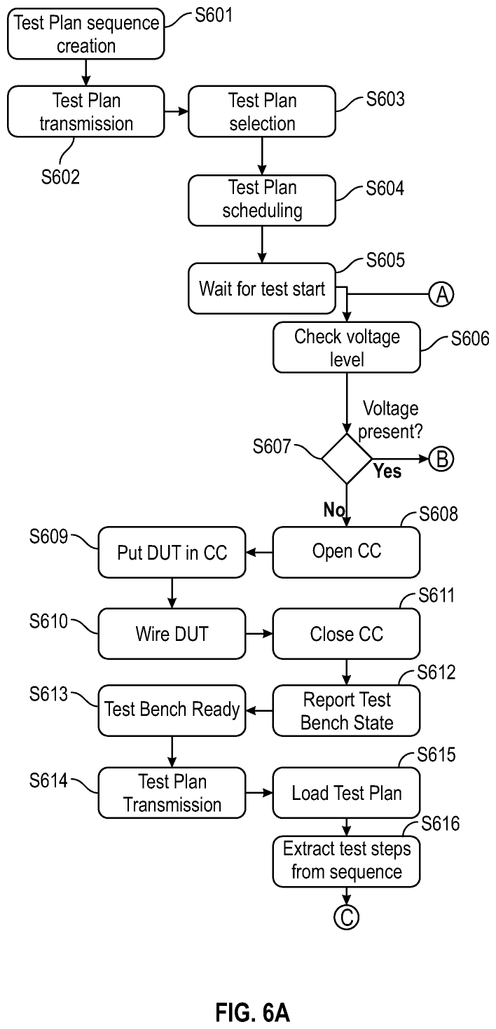

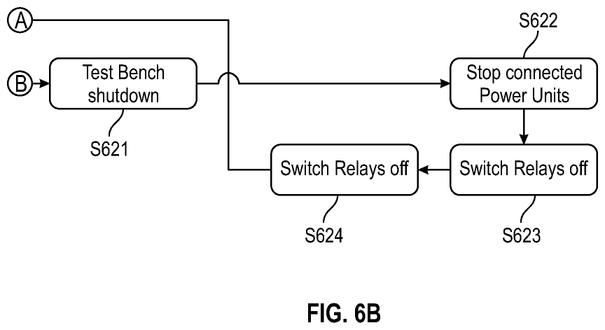

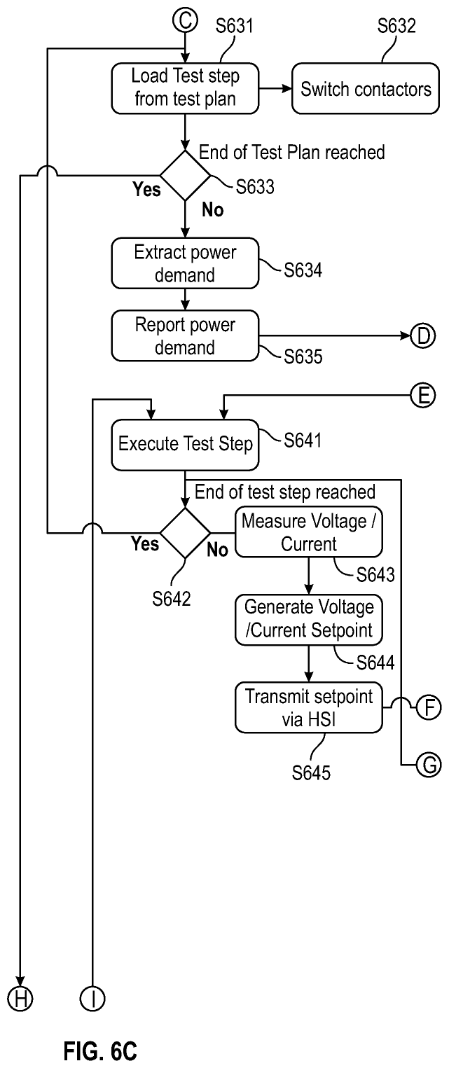

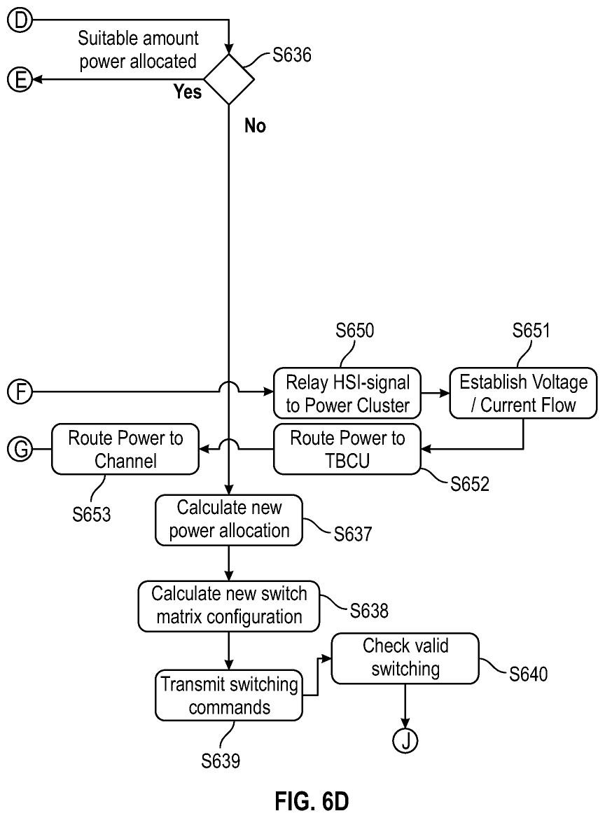

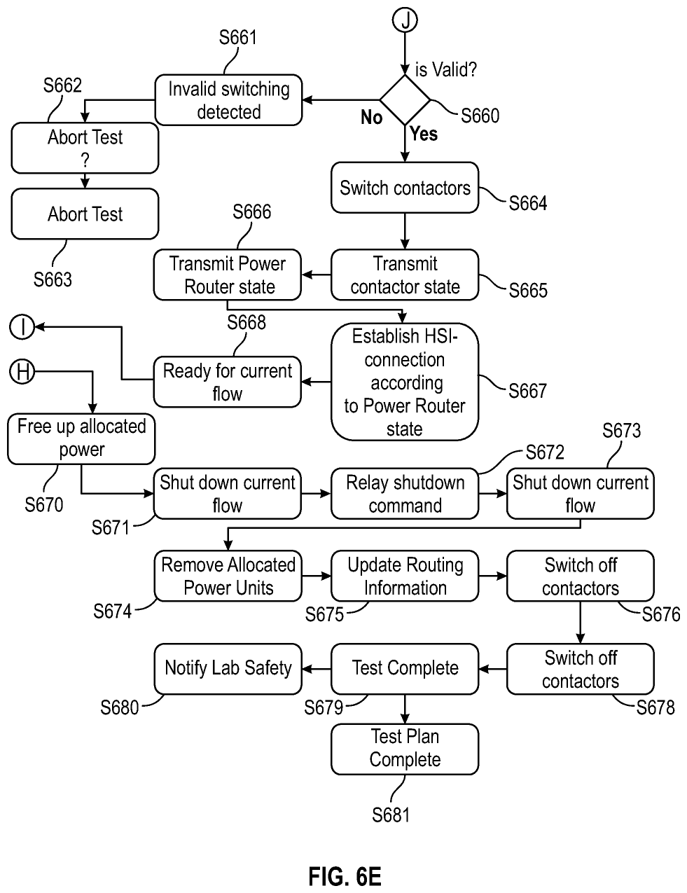

FIG. 6A, FIG. 6B, FIG. 6C, FIG. 6D and FIG. 6E are an illustrative view of a method for intelligent power allocation for high-power test laboratories, in accordance with a representative embodiment.

The method of FIG. 6A, FIG. 6B, FIG. 6C, FIG. 6D and FIG. 6E starts at S601 by creating a test plan sequence for each DUT.

At S602, the test plan is transmitted to a server (not shown), which may store the test plans for DUT

At SS603, the test plan is selected for implementation.

At S604, the test plan is scheduled.

At S605, the method of FIG. 6A, FIG. 6B, FIG. 6C, FIG. 6D and FIG. 6E includes waiting for the test to start.

At S606, a voltage level is checked.

At S607, a determination is made as to whether a voltage is present.

If no voltage is present (S607=No), at S608 the climate chamber is opened, and at S609 the device under test is put in the climate chamber.

At S610, the device under test is wired, and at S611 the climate chamber is closed.

At S612 the test bench state is reported, and at S613 the test bench is determined to be ready.

At S614, the test plan is transmitted to the corresponding TBCU, and at S615, the test plan is loaded in the TBCS of the TBCU.

At S616, test steps are extracted from the sequence in the test plan.

If voltage is present at S607 (S607=Yes), the test bench is shut down at S621. The power cluster is commanded to stop the connected power units at S622, and relays are switched off at the power router at S623 and at the test bench control unit at S624 so that the method returns to S607.

After S616, a test step is loaded from the test plan at S631. Contactor(s) inside the TBCU are also switched at S632 based on loading the test step at S631.

At S633, a determination is made as to whether the end of the test plan is reached.

If the end of the test plan is not reached (S633=No), power demand is extracted at S634 and reported to the power allocation manager at S635.

A determination is made at S636 whether a suitable amount of power is currently allocated, and if so (S636=Yes), the test step loaded at S631 is executed at S641.

Another determination is made at S641 whether the end of the test step is reached, and when the end of the test step is reached (S642=Yes), the method returns to S631 to load another test step from the test plan.

When the end of the test step is not reached at S642 (S642=No), at S643 the voltage and the current for the channel are measured at the TBCU, at S644 the voltage/current setpoint is generated inside the control unit of the TBCU, and at S645 the setpoint is transmitted via a high-speed interface (HSI) to the power distributor of the power allocation manager.

At S650, the HSI signal is relayed to corresponding power unit inside the power cluster, and at S651 the PU establishes the commanded setpoint of voltage or current. At S652, power is routed to the test bench control unit over the closed contacts inside the switch box of the power router, and at S653 power is routed over the TBCU to the specific channel being tested, after which the method returns to S642.

If a suitable amount of power is not allocated by the power allocation controller of the power allocation manager at S636 (S636=No), a new power allocation is calculated at S637 and a new switch matrix configuration is calculated at S638. Switching commands are transmitted to the power router at S639, and at S640 a check is made by the programmable logic controller of the power router as to whether the switching is valid.

A determination is made at S660 as to whether the switching is valid. If the switching is not valid (S660=No), invalid switching is detected at S661, a determination is made by the TBCS whether to abort the test at S662, and the test is aborted at S663.

If the switching is valid (S660=Yes), contactors are switched at S664, the contactor state is transmitted back to the power allocation controller inside the power allocation manager at S665, and the power router state is transmitted to the power distributor at S666. At S667, a HSI connection is established according to the power router state. At S668, the HSI connection is ready for current flow and the method returns to S641 to execute the test step.

When the end of the test plan is reached (S633=Yes), at S670 the test bench control system frees the allocated power and at S671 the control unit shuts down the current flow from the test. At S672, a relay shutdown command is relayed and at S673 the current flow is shut down based on the shutdown command.

At S674, power units allocated for the test by the power allocation manager are removed from the test and made available for other tests. At S675, routing information is updated. At S676, contactors are switched off.

At S679, the test is deemed complete at the test bench control system and at S680 the lab safety monitor is notified.

At S681, the method of FIG. 6A, FIG. 6B, FIG. 6C, FIG. 6D and FIG. 6E is complete.

In the method of FIG. 6A, FIG. 6B, FIG. 6C, FIG. 6D and FIG. 6E, power from the plurality of power units is dynamically allocated to a plurality of test bench control units, such as a first test bench control unit and a second test bench control unit, based on test plans for the first device under test and the second device under test and based on requests from the plurality of test bench control units.

Accordingly, power allocation manager for intelligent power allocation for high-power test laboratories enables clustering of power units in a test facility, so that power from each power unit in a cluster may be individually routed by a power router to where the power is needed. Power from power units may be intelligently and dynamically allocated to test channels so that multiple devices under test may be simultaneously tested using power from the same cluster using a logical allocation.

Although power allocation manager for intelligent power allocation for high-power test laboratories has been described with reference to several exemplary embodiments, it is understood that the words that have been used are words of description and illustration, rather than words of limitation. Changes may be made within the purview of the appended claims, as presently stated and as amended, without departing from the scope and spirit of power allocation manager for intelligent power allocation for high-power test laboratories in its aspects. Although power allocation manager for intelligent power allocation for high-power test laboratories has been described with reference to particular means, materials and embodiments, power allocation manager for intelligent power allocation for high-power test laboratories is not intended to be limited to the particulars disclosed; rather power allocation manager for intelligent power allocation for high-power test laboratories extends to all functionally equivalent structures, methods, and uses such as are within the scope of the appended claims.

The illustrations of the embodiments described herein are intended to provide a general understanding of the structure of the various embodiments. The illustrations are not intended to serve as a complete description of all of the elements and features of the disclosure described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. § 1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The preceding description of the disclosed embodiments is provided to enable any person skilled in the art to practice the concepts described in the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

1. A battery pack test system, comprising:
a power allocation manager comprising a power cluster with a plurality of power units and a power router that routes power from each of the plurality of power units, wherein the power allocation manager is configured to dynamically switch allocations of power from individual power units of the plurality of power units to a plurality of test channels each connected to a different device under test; and
a plurality of test bench control units each configured to interface with the power router and a different corresponding device under test, and each comprising a plurality of measurement sensors for measuring characteristics of the corresponding device under test.

2. The battery pack test system of claim 1, wherein the power router comprises:
a plurality of switches configured to dynamically switch the allocations of power from the individual power units of the plurality of power units to the test channels.

3. The battery pack test system of claim 2, wherein the power allocation manager further comprises:
a power allocation controller configured to dynamically control the plurality of switches.

4. The battery pack test system of claim 3, wherein:
the power allocation controller comprises a memory that stores instructions and a processor that executes the instructions, and
the power allocation controller is configured to receive power requests from each of the test bench control units, generate an optimal routing plan for allocating power from the individual power units of the plurality of power units to the plurality of test channels, and provide the optimal routing plan to the power router to dynamically control the plurality of switches.

5. The battery pack test system of claim 1, wherein the power router comprises:
a switchbox with a plurality of switches configured to connect some or all of the power units to some or all of the test bench control units.

6. The battery pack test system of claim 1, wherein each test bench control unit comprises a plurality of contactors configured to connect the power allocation manager to the corresponding device under test and to disconnect the power allocation manager from the corresponding device under test.

7. The battery pack test system of claim 1, wherein each test bench control unit is reconfigurable to adapt to multiple different devices under test.

8. A battery pack test system comprising:
a power cluster with a plurality of power units; and
a power router that routes power from each of the plurality of power units, wherein the power allocation manager is configured to dynamically switch allocations of power from individual power units of the plurality of power units to a plurality of test channels each connected to a different device under test.

9. The battery pack test system of claim 8, wherein the power router is configured to interface with a plurality of test bench control units each configured to interface with the power router and a different corresponding device under test, and each comprising a plurality of measurement sensors for measuring characteristics of the corresponding device under test.

10. The battery pack test system of claim 8, wherein the power router comprises:
a plurality of switches configured to dynamically switch the allocations of power from the individual power units of the plurality of power units to the test channels.

11. The power router of claim 10, further comprising:
a programmable logic controller configured to dynamically control the plurality of switches.

12. The battery pack test system of claim 8, further comprising:
a power allocation controller comprising a memory that stores instructions and a processor that executes the instructions, and configured to receive power requests from each of a plurality of test bench control units, generate an optimal routing plan for allocating power from the individual power units of the plurality of power units to the plurality of test channels, and provide the optimal routing plan to the programmable logic controller to dynamically control the plurality of switches.

13. A battery pack test system, comprising:
a first test bench control unit configured to interface with a power router and a first device under test, and comprising a plurality of measurement sensors for measuring characteristics of a corresponding device under test; and
a second test bench control unit configured to interface with the power router and a second device under test, and comprising a plurality of measurement sensors for measuring characteristics of a corresponding device under test, wherein the first test bench control unit and the second test bench control unit are configured to receive power from a power cluster with a plurality of power units which are dynamically allocated to the first test bench control unit and the second test bench control unit based on test plans for the first device under test and the second device under test.

14. The battery pack test system of claim 13, further comprising:
a power allocation manager comprising the power cluster with a plurality of power units and the power router, wherein the power allocation manager is configured to dynamically switch allocations of power from individual power units of the plurality of power units to a plurality of test channels based on requests from the first test bench control unit and the second test bench control unit.

15. The battery pack test system of claim 14, wherein the power router comprises:
a plurality of switches configured to dynamically switch allocations of power from individual power units of the plurality of power units to the plurality of test channels.

16. The battery pack test system of claim 15, wherein the power router further comprises:
a programmable logic controller configured to dynamically control the plurality of switches.

17. The battery pack test system of claim 16, wherein:
the power allocation controller comprises a memory that stores instructions and a processor that executes the instructions, and
the power allocation controller is configured to receive power requests from each of the test bench control units, generate an optimal routing plan for allocating power from the individual power units of the plurality of power units to the plurality of test channels, and provide the optimal routing plan to the power router to dynamically control the plurality of switches.

18. The battery pack test system of claim 13, wherein the power router comprises:
a switchbox with a plurality of switches configured to connect some or all of the power units to some or all of the test bench control units.

19. The battery pack test system of claim 13, wherein each test bench control unit comprises a plurality of contactors configured to connect a power allocation manager to the corresponding device under test and to disconnect the power allocation manager from the corresponding device under test.

20. The battery pack test system of claim 13, wherein each test bench control unit is reconfigurable to adapt to multiple different devices under test.
